(19) United States
(12) Patent Application Publication
(10) Pub. No.: US 2011/0051384 A1
(43) Pub. Date: Mar. 3, 2011

(54) PRINTED CIRCUIT BOARD ELEMENT HAVING AT LEAST ONE COMPONENT EMBEDDED THEREIN AND METHOD FOR EMBEDDING AT LEAST ONE COMPONENT IN A PRINTED CIRCUIT BOARD ELEMENT

(76) Inventors: Arno Kriechbaum, Leoben (AT); Wolfgang Bauer, Graz (AT); Johannes Stahr, Bruck an der Mur (AT); Sabine Liebfahrt, Parschlug (AT)

(21) Appl. No.: 12/162,016

(22) PCT Filed: Feb. 2, 2007
(86) PCT No.: PCT/AT2007/000045

§ 371 Date: Oct. 27, 2008

(30) Foreign Application Priority Data
Feb. 2, 2006 (AT) A 160/2006

(51) Int. Cl. H05K 1/18; B32B 37/02

(52) U.S. Cl. 361/762; 361/764; 156/280

(57) ABSTRACT

A printed circuit board element (1) comprising at least one component (2) embedded between a base (4) and a cover layer (6), which component (2) is adhered to the base (4) by means of an adhesive film section (3).

The invention relates to a printed circuit board element comprising at least one prefabricated electric or electronic component, in particular a chip, embedded between a base and a cover layer.

Furthermore, the invention relates to a method for embedding at least one electric or electronic component, in particular a chip (semiconductor component) in a printed circuit board element, wherein the component is adhered to a base, whereupon a cover layer is applied on top of the base including the component by pressure.

Apart from externally equipping printed circuit boards with electric and/or electronic components and, in particular, active electronic components or integated circuits, respectively, which commonly are termed chips, it is an increasing desire in printed circuit board technology to embed such components, in particular chips, also in the interior of the respective printed circuit board element, wherein the components are enclosed between individual layers of the printed circuit board element. A technique therefor has been disclosed in U.S. Pat. No. 6,396,153 B, e.g., wherein on a side which later comes to lie in the interior, a connecting layer of insulating material is coated with a polymer adhesive, to which then a chip is glued. Subsequently, a substrate layer is applied to the adhesive layer and shaped around the chip, e.g. by injection moulding or by compression, so that, finally, the chip will be embedded between this substrate and the connecting layer through which the chip will be contacted. A similar application of chips to substrates by means of an adhesive layer has been disclosed in DE 4 433 833 A, EP 611 129 A and U.S. Pat. No. 5,564,181 A. This technology is complex, and also the adhesive layer applied facewise as an additional layer, also present externally of the chip, is disturbing.

On the other hand, it has been known (cf. e.g. DE 196 42 488 A and DE 199 54 941 A) to fasten chips to printed circuit board elements by merely locally applied adhesive, in particular in the course of embedding chips in printed circuit board elements. For embedding in printed circuit board elements, however, chips that are as thin as possible should be used, and in particular so-called “thinned” chips, i.e. chips with a substrate side that has been considerably ground off, of course without negatively affecting the circuit contained in the chip, chip thicknesses e.g. in the order of 50 μm or 70 μm being attained, whereas standard chips have a thickness of 700 μm, e.g. Such thinned chips naturally are highly flexible so that they are bent when they are pressed onto amounts of adhesive applied locally in the form of droplets, since these amounts of adhesive are not plane, but have a cambered shape. Moreover, with the thinned chips, a facewise distribution of the adhesive previously applied to the substrate or to the lower side of the chip by pressing on, as desired, is not possible, so that—apart from a bending of the chip—also an insufficient gluing-adhesion may be the consequence. A further disadvantage is that here, in the case of bent chips, their subsequent contacting, after their inclusion between printed circuit board layers is a problem since the positions of the contact sites on the chip have shifted relative to the set position due to the bending of the chip.

It is now an object of the invention to remedy this situation and to propose a technique by which the components, in particular also thinned chips, can be fastened by gluing to the respective base when embedding them in printed circuit board elements, wherein the components are treated gently and their positions can be exactly defined. Furthermore, the invention aims at enabling the gluing fastening of the components in a particularly economical manner, with an adhesive being also merely locally applied.

To achieve this object, the invention provides a printed circuit board element, and a method, respectively, as defined in the independent claims. Advantageous embodiments and further developments are indicated in the dependent claims.

Thus, according to the invention, adhesive film sections, or adhesive strip sections, respectively, are used to fix the components on the respective bases by adhering. These sections are separated, e.g. by cutting or punching, from prefabricated, in particular strip-shaped adhesive films which, preferably, are provided in the form of rolls, and the sections have a predetermined, uniform thickness, e.g. in the order of from 10 μm to 15 μm, and preferably they have a thickness of approximately 12 μm. These adhesive films, or strips, respectively, in particular are thermo-setting, the adhesive, e.g., being pre-cured by infrared irradiation after a separate attachment of the respective section on the substrate and finally, after attachment of the component, being completely cured in an oven. The adhesive film sections are separated substantially in the dimensions of the components, e.g. cut out or punched out, and, according to an advantageous embodiment, separately before attachment of the components on the base. In this instance, the adhesive film sections are pressed on during their attachment after they have been positioned and, to a certain degree, pre-cured—optionally also by using a heated tool. One possibility may further consist in that the adhesive film sections are applied to the base and pressed on, the base being heated from the opposite side thereof to thereby cure the adhesive film sections to a limited extent, i.e. pre-cure them, wherein, optionally, also the components are heated. Pre-curing has the purpose of attaching the adhesive film section to the base with sufficient strength, yet the adhesive film section shall remain sufficiently sticky so as to adhere the respective component thereto by compression.

The adhesive films which, in particular, are strip shaped, may have a per se conventional structure, such as a structure comprising a carrier film coated on both sides with an adhesive, wherein cover films may in turn be applied over these glue layers. Another possibility consists also in omitting the carrier film and only providing an adhesive layer, e.g. likewise between two cover films. The cover film enables an increase in stability, and it may, e.g., consist of polyimide. As the cover films, e.g. polyethylene films or polyethylene therephthalate films (PE films or PET films) may be used. As the adhesive, a per se conventional polymer glue, such as with a low elasticity module, preferably is used in combination with an epoxy resin as well as fillers. Also a modified polyimide may be used in combination with an epoxy resin.

When using adhesive film sections with cover foils on both sides thereof, it is preferably proceeded such that the one, lower cover film, eg. a PE film, is pulled off before the adhesive film section is applied to the base so as to thereby adhere the adhesive film section to the base, and that the other, upper cover film, e.g. a PET film, is pulled off only shortly before the component is applied so as to protect the adhesive layer up to that point of time.

An advantageous possibility also consists in previously attaching the adhesive film sections to the component to that side thereof which is to be connected to the base and to thus attach the respective component including the adhesive film section on the base. In this instance, it may advantageously be proceeded such that an adhesive film is previously attached to a wafer containing a plurality of components, whereupon the components together with the adhesive film sections are separated from each other and are each attached to the associated base.

For complete curing of the glue of the respective adhesive film section, the base together with the component glued thereto is suitably introduced into an oven and heated, e.g. to a temperature of from 130° C. to 150° C. or to 170° C. In this instance, it may also be advantageous to carry out this complete curing of the glue in a reactive or in an inert atmosphere, in particular in a nitrogen atmosphere.

After the respective component has been glued to the base, a resin-copper cover layer, such as a so-called RCC film (RCC resin coated copper film)), can be applied over the base including the component by pressure, and subsequently contact holes can be applied in this cover layer by laser drilling. Subsequently, a metallization by electroplating will be effected in the region of the contact holes so as to contact the embedded components or conductive layers, whereupon, finally, patterning will be effected on the outer conductive layer (copper layer) by photolithography.

The invention will be explained in more detail hereinafter by way of preferred exemplary embodiments to which, however, it shall not be restricted, and with reference to the drawings. In the drawings, in detail,

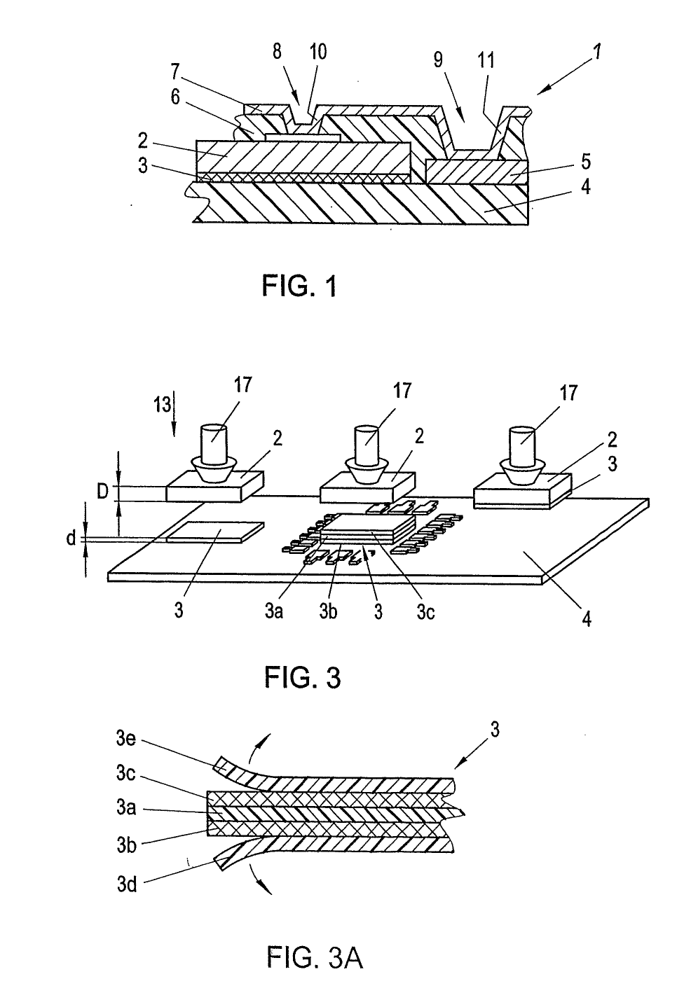

FIG. 1 schematically shows a cross-section through a part of a multilayer-printed circuit board element comprising an embedded component, e.g. a thinned chip;

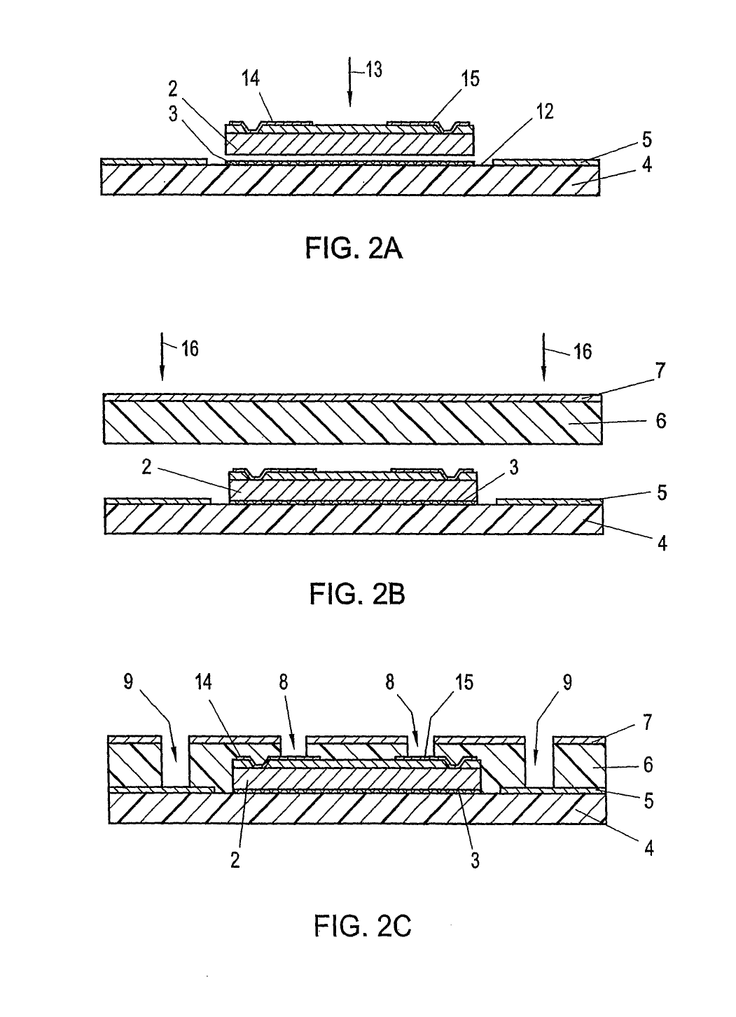

FIGS. 2A to 2E show consecutive steps in the production of such a printed circuit board element, with a component being embedded, in schematic partial cross-sections;

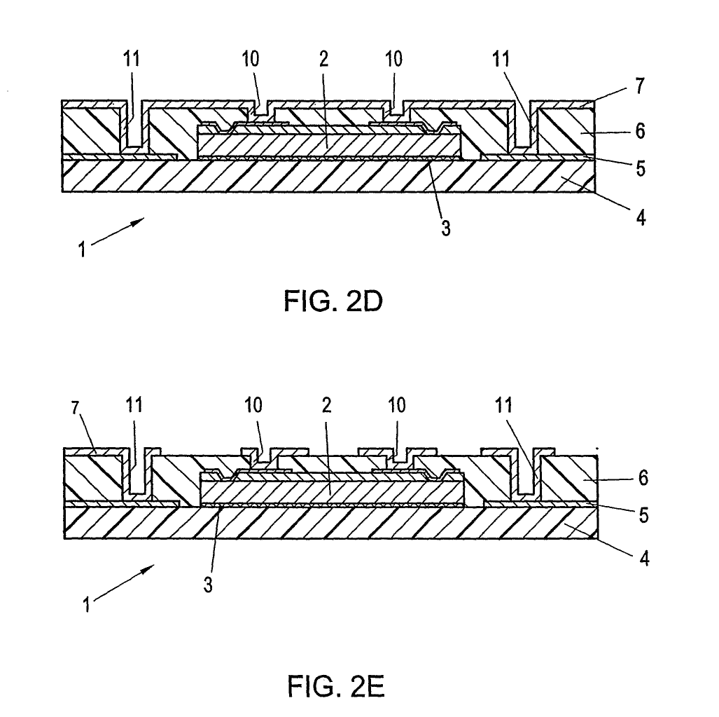

FIG. 3 schematically shows—side by side—various options for applying a component on a base of a printed circuit board element in perspective illustrations;

FIG. 3A shows a schematic section through an embodiment of an adhesive film section;

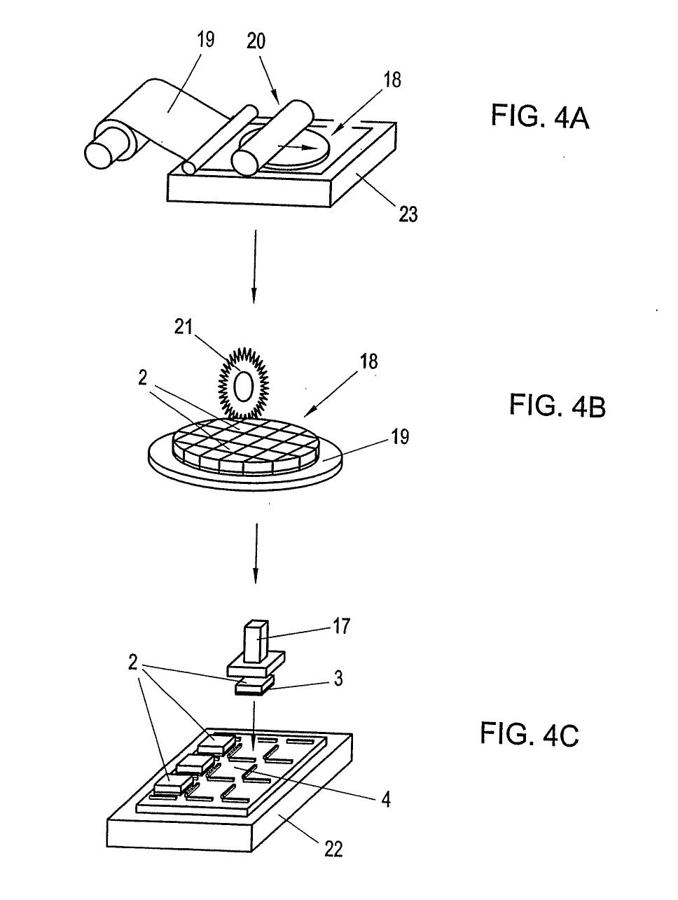

FIGS. 4A to 4C show an advantageous option for applying a wide, strip-shaped adhesive film material on a chip wafer (FIG. 4A) and the subdivision of the wafer including the adhesive film into chips with adhesive film sections (FIG. 4B) as well as the application of the chips including the adhesive film sections fixed thereto to a substrate or to a base of a printed circuit board element (FIG. 4C); and

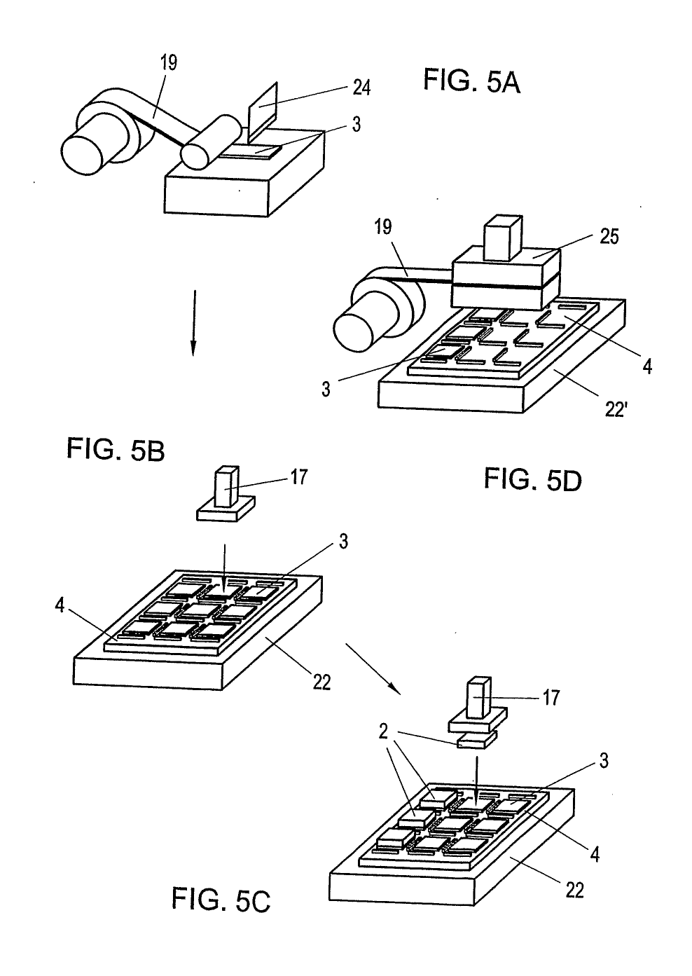

FIGS. 5A to 5D show a modified embodiment of the method for applying chips (or, generally, components) on a base by using adhesive film sections, wherein the sections are previously separated from an adhesive tape, either by means of a cutting tool (FIG. 5A) or by means of a punching tool (FIG. 5D), then are separately applied to the base (FIG. 5B) and, finally, the chips are glued to these adhesive film sections (FIG. 5C).

In FIG. 1, a part of a printed circuit board element 1 is schematically illustrated, which contains an embedded electric component in the form of a thinned chip 2. To simplify matters, in the following reference will always be made to such a chip 2 by way of example, within the scope of the invention, however, embedding of other electric or electronic components, in particular passive components, such as resistors, capacitors, ESD (Electro static discharge) protection elements, laser diodes, photodiodes etc. in a printed circuit board element 1 in the present manner is also provided. These are discrete components, wherein preferably the thickness of these components—either right from the beginning, by the production process, such as with capacitors, or by a subsequent rear-side thinning—is approximately from 50 μm to 70 μm. By embedding, such thin components can be safely enclosed by the resin so as to protect them from moisture or from mechanical wear, e.g., a corresponding dielectric thickness then being present above the component in this instance and a plane surface being attained. This is important for laser drilling processes, on the one hand, yet also for other processes which require a plane surface.

The component, or chip 2, respectively, is glued to a base 4, e.g. a common FR4 base material (resin core, in particular with conductive layer) or substrate, as is conventionally used in printed circuit board technology, by means of a section 3 of a strip-shaped adhesive film, termed adhesive film section 3 hereinafter. Accordingly, the printed circuit board element 1 may comprise a conducting track 5, e.g. in the form of a patterned Cu layer, on the base 4 in a per se common way, which conducting track leads to further electric components not further illustrated in the printed circuit board element 1; above this conducting track 5 as well as above the chip 2, a cover layer 6 of resin having an upper copper coating 7 is applied, which, e.g., may be a common RCC film (resin coated copper film, i.e. a resin-copper film laminate). Furthermore, for contacting the chip 2 as well as the conducting track 5, laser bores, or micro-vias 8, 9, respectively, are provided in this cover layer 6, which micro-vias have galvanic metallizations 10 and 11, respectively, on their side walls.

In FIG. 2A, the application of a component, or chip 2, respectively, on such a base 4 is shown in detail. As can be seen, at first a clearance in the conductive coating, i.e. in the conducting track 5, is provided on the base 4, i.e. on the printed circuit board core, in a region 12, and in this region 12, an adhesive strip section 3 has already been positioned and glued on by pressing on and also pre-cured to a predetermined extent so that its adhesion to the base 4 is ensured. The chip 2 is now applied to this adhesive strip section 3 by pressing it thereto, as indicated by arrow 13, and adhered. The adhered state of the chip 2 can be seen in the lower part of FIG. 2B. On its upper side, the chip 2, moreover, includes contact regions 14, 15 which will be cantacted later on by means of the laser bores 8 already mentioned by way of FIG. 1 made through the cover layer 6.

After attachment of the respective chip 2 on the base 4, complete curing of the adhesive material of the adhesive strip section 3 will occur which may take place in an oven in a nitrogen atmosphere at a temperature of, e.g., from 130° C. to 150° C. or also from 150° C. to 170° C., depending on the type of materials used.

With the help of the adhesive strip section 3, a precise, secure application and adhesive attachment of the chip 2 is possible, even if these chips 2 are so-called thinned chips, which, as mentioned, due to grinding off a substantial part of the chip substrate may have a thickness of merely approximately 50 μm, e.g., more generally from 10 μm to 70 μm (instead of approximately 700 μm, e.g.), and which therefore are highly flexible and sensitive. The conventional application of a liquid glue in the form of drops would be a problem for such thinned chips, since with the thinned chips, there could be no planar distribution of the glue drops when the chips are pressed onto the latter, apart from the fact that extraordinarily slight amounts of glue would be possible so that dosing would be difficult and, thus, in this standard procedure a precise and reliable fastening of the chips by gluing to the base 4 would not be possible. On the other hand, with the help of the adhesive fastening described by using adhesive strip sections 3, an exact application and a good adhesion of the chip 2 is rendered possible within the scope of the mechanical properties required.

After the application of the adhesive strip section 3 on the printed circuit board base 4, and of the chip 2 on the adhesive strip section 3, the base 4, preferably on a panel with a plurality of similarly equipped printed circuit board bases, will be introduced into an oven, as mentioned before, so as to completely cure the adhesive. This may be in a reactive or also in an inert atmosphere, e.g. nitrogen.

Subsequently, in the course of a conventional pressing with an RCC film 6 which has an upper copper layer 7 and which may consist of an epoxy resin, e.g., embedding of the chip 2 in the interior of the preliminary printed circuit board element can be performed by the application of temperature and pressure (cf. the arrows 16 in FIG. 2B). Again, depending on the materials used, the temperature may be 200° C. or 220° C., and the pressure during this pressing is 20 bar, or 30 bar, e.g.

In the multilayer printed circuit board element thus produced, the bores 8, 9 are then made by means of laser beams for contacting the inwardly located components, in particular chips 2, as well as the conducting tracks 5; the result of this method step is shown in FIG. 2C.

Subsequently, as shown in FIG. 2D, the contact sites 14, 15 of the components 2 as well as the conducting tracks 5 in the interior of the multilayer are contacted by galvanic metallization, wherein the walls of the bores 8, 9 are coated with copper so that the metallizations 10, 11 will be obtained. Subsequently, by means of a conventional photolithographic process, the upper copper layer 7 is patterned, so that finally the printed circuit board element 1 as shown in FIG. 2E is obtained.

In FIG. 3, three possible ways of fixing a component with the assistance of adhesive film sections 3 are schematically indicated, side by side for the sake of simplicity, and in combination with a single substrate core as base 4.

In detail, on the left-hand side it is shown that an adhesive film section 3 merely consisting of adhesive material—with possible lower and upper cover films already pulled off—has been previously positioned on the base 4, pressed thereto and pre-cured. Subsequently, with the assistance of a tempered punch-suction tool 17, a component 2 held on the tool 17 by means of vacuum is put into position under the control of a computer and pressed onto the adhesive film section 3 according to arrow 13 (cf. also FIG. 2A). As has been mentioned, the thin or thinned component 2 may, e.g., have a thickness in the order of merely approximately 50 μm, cf. the measure D in FIG. 3, and the adhesive film section 3 may, e.g., have a thickness d in the order of merely from 8 μm to 15 μm.

In the central part of FIG. 3, a comparable attachment of a thinned or thin component 2 by means of a tool 17 is shown, yet here an adhesive film section 3 is shown which has a carrier film 3a between two layers of adhesive 3b, 3c, see here also FIG. 3A. Moreover, in its original state, this adhesive film section 3 may have a lower cover film 3d and an upper cover film 3e, as illustrated in FIG. 3A, these cover films 3d, 3e being pulled off when applying the adhesive film section 3, or the component 2, respectively, as schematically indicated in FIG. 3A. In detail, of course the lower cover layer 3d will at first be pulled off, whereupon the adhesive film section 3 is pressed onto the printed circuit board base 4. The upper cover film 3e preferably is pulled off only directly before attachment of the component 2 so as to protect the upper adhesive layer 3c as long as possible.

Quite generally, in case of an adhesive film material having a single adhesive layer (see FIG. 3, left-hand side), i.e. without a carrier film, a thickness of between, e.g., 10 μm and 50 μm (without cover film) is given, whereas an adhesive film section with adhesive layers 3b, 3c on either side of a carrier film 3a may very well be somewhat thicker, such as 12 μm to 200 μm. The upper cover film may, e.g, be made of PET and have a thickness of 50 μm, whereas the lower cover film to be pulled off at first may consist of PE material, and may have a thickness of 25 μm.

As the adhesive material, a polymer adhesive combination is suitable, which may also contain an epoxy resin and which, e.g., may be produced on the basis of a modified polyimide or of a polymer having a low module of elasticity.

Finally, on the right-hand side in FIG. 3, a further possibility for fastening a component is shown, wherein the adhesive film section 3 previously has been attached at first to the lower side of the respective component 2, and the component 2 including the adhesive film section 3 is attached and adhered in the desired position on the base 4 by means of the tool 17.

Such a previous attachment of adhesive film sections 3 on the components 2 results advantageously if, as shown in FIGS. 4A, 4B and 4C, an appropriately wide adhesive strip, i.e. strip-shaped adhesive film material 19, is attached to the lower side of a wafer 18 containing a plurality of chips 2 or the like components. In FIG. 4A, at 20 it is schematically indicated how the adhesive film material 19 is laminated to the wafer 18 by means of a roller, after a possible lower PE cover foil has been pulled off. The upper PET cover film which in the attachment according to the illustration on the right-hand side of FIG. 3 will then come to lie on the lower side, may also be pulled off immediately, or it may be pulled off directly before applying the chip 2 on the printed circuit board base 4.

After the wafer rear side has been laminated in this way with adhesive film material 19, as illustrated in FIG. 4A, the wafer 18 is subdivided into the individual chips 2 according to FIG. 4B, which has been quite schematically indicated by means of a cutting tool 21.

Subsequently, the chips 2 with the adhesive film sections 3 thus obtained directly on the lower side of the chip 2 will be attached to the printed circuit board base 4 for which the temperature-adjusted suction tool 17 already explained by way of FIG. 3 can be used.

The base 4 may be heated from its lower side by means of a heating block 22, just as a heated block 23 kept, e.g., at a temperature of approximately 80° C. can be used during the application of the adhesive film material 19 on the wafer 18 according to FIG. 4A so as to already partially cure the adhesive material in each case.

In FIGS. 5A to 5D, as an alternative to FIGS. 4A to 4C, a technique is illustrated in which the individual adhesive film sections 3 previously have been separated by transverse cutting from a strip-shaped adhesive film material 19 by means of a cutting tool 24, e.g. In this case, the one cover film, i.e. the PE cover film, has been pulled off previously, and then the individual adhesive film sections 3 are cut and attached by means of the tool 17 on the printed circuit board base 4, cf. FIG. 5B, wherein the printed circuit board base 4 again may lie on a heated block 22 so as to already preliminarily cure the adhesive material of the adhesive film sections 3 to a certain extent.

As an alternative, according to FIG. 5D a punching tool 25 can be used for punching and directly pressing the adhesive film sections 3 onto the base 4. In this instance, the base 4 may rest on a modified heating block 22′ kept, e.g., at a temperature of 140° C.

Subsequently, no matter how the adhesive film sections 3 have been applied to the base 4, the components 2 on the adhesive film sections 3 are attached to the base 4 by means of the tool 17. As mentioned above, a possibly present upper PET cover foil will previously be pulled off the adhesive film sections 3.

As shown in FIG. 4A or 5A and 5D, respectively, the adhesive film material 19 may be provided as a rolled-up material and may be pulled off the roll so as to obtain the individual adhesive film sections 3.

Before attaching the adhesive film sections 3 (or the component 2 together with the adhesive film sections 3 previously attached thereto) on the base 4, this base may also be irradiated by an infrared lamp in the attachment positions and pre-heated, such heating period being from 10 to 20 seconds, depending on the output of the infrared lamp. In tests, the force applied when pressing on the adhesive film sections 3, or the components 2, respectively, was 37N. The curing temperature for the adhesive of the adhesive film sections 3 was 150° C., and 170° C., respectively.

1. A printed circuit board element (1) comprising at least one prefabricated electric or electronic component (2), in particu-lar a chip, embedded between a base (4) and a cover layer (6), characterised in that the component (2) is adhered to the base (4) by means of an adhesive film section (3).

2. The printed circuit board element according to claim 1, characterised in that the component (2) is a thinned component.

3. The printed circuit board element according to claim 2, characterised in that the thinned component (2) has a thickness of from 10 μm to 70 μm, in particular approximately 50 μm.

4. The printed circuit board element according to claim 1, characterised in that the adhesive film section (3) has a thickness in the order of 10 μm, approximately 12 μm, e.g.

5. The printed circuit board element according to claim 1, characterised in that the adhesive film section (3) is thermo-setting.

6. The printed circuit board element according to claim 1, characterised in that the component (2) is contacted through the cover layer (6) including a synthetic resin layer.

7. The printed circuit board element according to claim 6, characterised in that metallized laser bores (8) are provided in the cover layer (6) for contacting the component (2).

8. A method for embedding at least one electric or electronic component (2), in particular a chip, in a printed circuit board element (1), wherein the component (2) is adhered to a base (4), whereupon a cover layer (6) is applied on top of the base (4) together with the component (2) by pressure, characterised in that the component (2) is adhered to the base (4) by means of an adhesive film section (3).

9. The method according to claim 8, characterised in that the adhesive film section (3) is separately applied to the base (4) prior to application of the component (2).

10. The method according to claim 9, characterised in that the adhesive film section (3) is pressed and pre-cured during its attachment.

11. The method according to claim 10, characterised in that the adhesive film section (3) is positioned and pressed on as well as, preferably, pre-cured by means of a positioning and pressing tool (17).

12. The method according to claim 11, characterised in that the positioning and pressing tool (17) is heated.

13. The method according to claim 10, characterised in that the adhesive film section (3), after having been positioned on the base (4), is pressed thereto, the base (4) being heated from the other side.

14. The method according to claim 13, characterised in that the component is additionally heated.

15. The method according to claim 9, characterised in that an adhesive film section (3) with cover films (3d, 3e) provided on both sides is used, and before application on the base (4), the one, lower cover film (3d) is pulled off, whereas the other, upper cover film (3e) is pulled off only after the attachment of the adhesive film section (3) and prior to the attachment of the component (2).

16. The method according to claim 8, characterised in that the adhesive film section (3) is previously adhered to the component (2) to its side facing the base (4), and is applied to the base (4) together with the component (2).

17. The method according to claim 16, characterised in that an adhesive film (19) is previously attached to a wafer (18) containing a plurality of components (2), whereupon the components (2) together with adhesive film sections (3) are separated from each other and are each attached to the associated base (4).

18. The method according to claim 8, characterised in that a strip-shaped adhesive film (19) is used from which the individual adhesive film sections (3) are separated, e.g. by cutting or by punching.

19. The method according to claim 8, characterised in that the base (4) together with the component (2) glued thereto is heated for a complete curing of the adhesive of the adhesive film section (3).

20. The method according to claim 19, characterised in that complete curing of the adhesive is carried out in a reactive at-mosphere.

21. The method according to claim 19, characterised in that complete curing of the adhesive is carried out in an inert atmosphere.

22. The method according to claim 19 of 21, characterised in that complete curing of the adhesive is carried out in a nitro-gen atmosphere.
